(19) United States
(12) Patent Application Publication
(10) Pub. No.: US 2006/0152240 A1
(43) Pub. Date: Jul. 13, 2006

(54) Probe device with micro-pin inserted in interface board

(75) Inventor: Chaeyoon Lee, Saha-gu (KR)

Correspondence Address: LAHIVE & COCKFIELD, 28 STATE STREET, BOSTON, MA, 02109, US

(73) Assignee: Leeno Industrial Inc., Gangseo-Gu (KR)

(21) Appl. No.: 11/332,079

(22) Filed: Jan. 13, 2006

(30) Foreign Application Priority Data
Jan. 13, 2005 (KR) 2005-3153

(51) Int. Cl. G01R 31/02

(52) U.S. Cl. 324/761

(57) ABSTRACT

Disclosed is a probe device for testing a semiconductor integrated circuit including a micro-pin adapted to make direct contact with the semiconductor integrated circuit and transmit an electric current to the semiconductor integrated circuit; a retaining block enclosing the micro-pin; an interface board having a groove, the micro-pin being inserted into the groove, to transmit an electric current to the semiconductor integrated circuit via the micro-pin; a micro-pin contact portion for improving contact between the micro-pin and the interface board; a mask board mounted on the interface board to retain the micro-pin so that the micro-pin does not detach from the interface board; and a mask board retainer for retaining the mask board on the interface board. The probe device can be constructed in a simple assembly process without soldering. This substantially reduces manufacturing time and cost. The probe device can be easily repaired.

### RELATED APPLICATION

This application claims priority to Korean patent application No. 2005-3153 filed on Jan. 13, 2005, the content of which is incorporated by reference.

### FIELD OF THE INVENTION

The present invention relates to a probe device having micro-pins inserted into an interface board. More particularly, the present invention relates to a probe device for inspecting the performance of semiconductor integrated circuits, the device including an interface board having grooves formed thereon, micro-pins inserted into the grooves, and a mask for covering the board.

### BACKGROUND OF THE INVENTION

When semiconductor devices are to be manufactured, a number of semiconductor devices are formed on a semiconductor wafer in a batch mode using precise photo transfer technology, for example, and are cut separately. In order to improve the productivity, it is customary to use a probe device in such a semiconductor device manufacturing process to test the electrical properties of semiconductor devices, which are half-completed, in a semiconductor wafer condition so that only those which have passed the test are subjected to a following process (e.g. packaging).

In the test, electrode pads of the devices formed on the semiconductor wafer are brought into contact with probe tips, and an electric current is applied to the probe tips, in order to measure electrical properties using a tester adapted to analyze input and output signals.

As recent semiconductor devices incorporate more functions in a compact size, the degree of integration of circuits are increasing, and electrode pads are becoming smaller with a narrower spacing between them. Consequently, hundreds or thousands of probe tips are necessary in the limited space of the probe device, and the probe tips must be controlled to contact the center of the electrode pads in an accurate and stable manner.

FIG. 1 briefly shows the construction of a conventional probe device.

The probe device 100 includes probe tips (or needle pins) 110, a support member 120, a circuit board 130, solder 140, a semiconductor integrated circuit 150, electrode pads 152, and a retaining block 160.

The probe tips 110 generally have the shape of a needle and are supported on the circuit board 130 by the support member 120 with one side thereof being coupled thereto by the solder 140, as shown in (a) of FIG. 1. The probe tips 110 are enclosed and protected by the retaining block 160, as shown in (b) of FIG. 1. The other side of the probe tips 110, which has the shape of a rod, is bent so that a slanted portion 110b is formed thereon, and a contact end 110a is formed on an end thereof.

The contact ends 110a of the probe tips 110 are brought into contact with the electrode pads 152 of the semiconductor integrated circuit 150 to test it. Compact electronic devices undergo a series of inspection steps during manufacturing processes to verify functionality and reliability. However, not all chips on the wafer pass the wafer probe test, and the yield rate is less than 100%.

The devices on the semiconductor wafer are cut into separate chips, by a cutting device for example, and those of the chips which have passed the test are assembled and packaged. Packaged devices are mounted on sockets on a burn-in board and are electrically actuated in a dynamic burn-in process for 8-72 hours at a temperature of 125-150° C., in order to destroy defective devices. The burn-in test is aimed to facilitate a destroying mechanism so that defective devices are initially destroyed. As a result, defective devices are screened by the functionality test before they are commercially available.

Packaged devices undergo a full functionality test and are operated at various operation rates to classify them according to the maximum operation rate.

However, conventional probe devices for the above tests have a problem in that, since the probe tips 110 are connected to the circuit board 130 by the solder 140, as shown in FIG. 1, it is difficult to dissemble and repair the probe devices even when malfunctioning. In addition, when a large number of probe tips 110 are used, they must be soldered separately for a long period of time at vast expense.

Furthermore, the contact between the probe tips 110 and the circuit board 130 or between the probe tips 110 and the semiconductor integrated circuit 150 is not reliable. In the case of the contact between the probe tips 110 and the semiconductor integrated circuit 150, bending of the end of the probe tips 110 increases the slant angle of the slanted portion 110b. As a result, repeated contact between the contact ends 110a and the electrode pads 152 continuously gives the contact ends 110a repeated pressure. This means that the contact ends 110a are pressed by the electrode pads 152 and generate slip at an undesirable degree. In the end, the contact ends 110a move out of the center of the electrode pads 152, when pressed by them, and even damage the pads in a worse case.

The needle-shaped probe devices have limitations in simultaneously testing a number of electrode pads 152 with a number of probe tips 110 and are hardly applicable to the above-mentioned wafer-level burn-in test.

### SUMMARY OF THE INVENTION

Accordingly, the present invention has been made to solve the above-mentioned problems occurring in the prior art, and an object of the present invention is to provide a probe device for inspecting the performance of semiconductor integrated circuits, the device including an interface board having grooves formed thereon, micro-pins inserted into the grooves, and a mask for covering the board.

In order to accomplish this object, there is provided a probe device for testing a semiconductor integrated circuit including a micro-pin adapted to make direct contact with the semiconductor integrated circuit and transmit an electric current to the semiconductor integrated circuit; a retaining block enclosing the micro-pin; an interface board having a groove, the micro-pin being inserted into the groove, to transmit an electric current to the semiconductor integrated circuit via the micro-pin; a micro-pin contact portion for improving contact between the micro-pin and the interface board; a mask board mounted on the interface board to retain the micro-pin so that the micro-pin does not detach from the interface board; and a mask board retainer for retaining the mask board on the interface board.

### BRIEF DESCRIPTION OF THE DRAWINGS

The above and other objects, features and advantages of the present invention will be more apparent from the following detailed description taken in conjunction with the accompanying drawings, in which:

FIG. 1 briefly shows the construction of a conventional probe device;

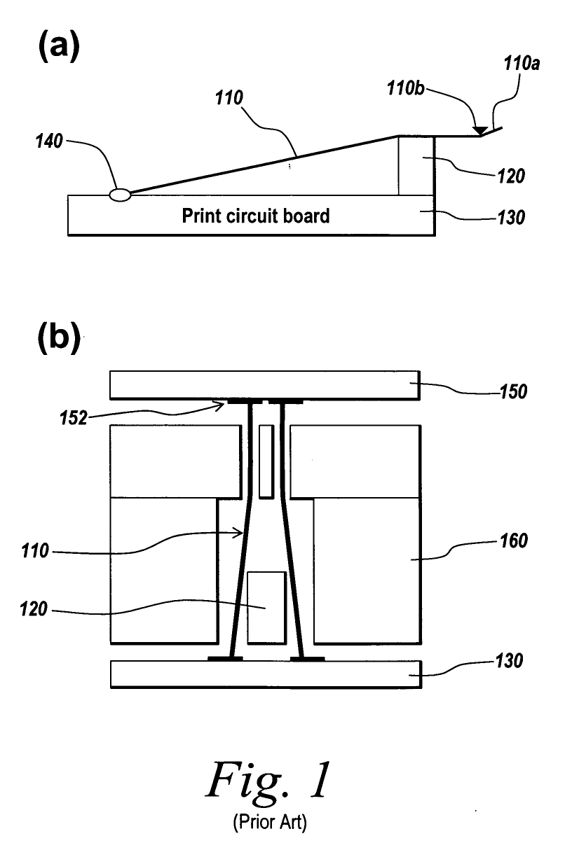

FIG. 2 shows the construction of a probe device having micro-pins inserted into an interface board according to an embodiment of the present invention; and

FIG. 3 is a sectional view showing a probe device having micro-pins inserted into an interface board according to an embodiment of the present invention.

### DETAILED DESCRIPTION OF THE PREFERRED EMBODIMENTS

Hereinafter, a preferred embodiment of the present invention will be described with reference to the accompanying drawings. In the following description and drawings, the same reference numerals are used to designate the same or similar components, and so repetition of the description on the same or similar components will be omitted.

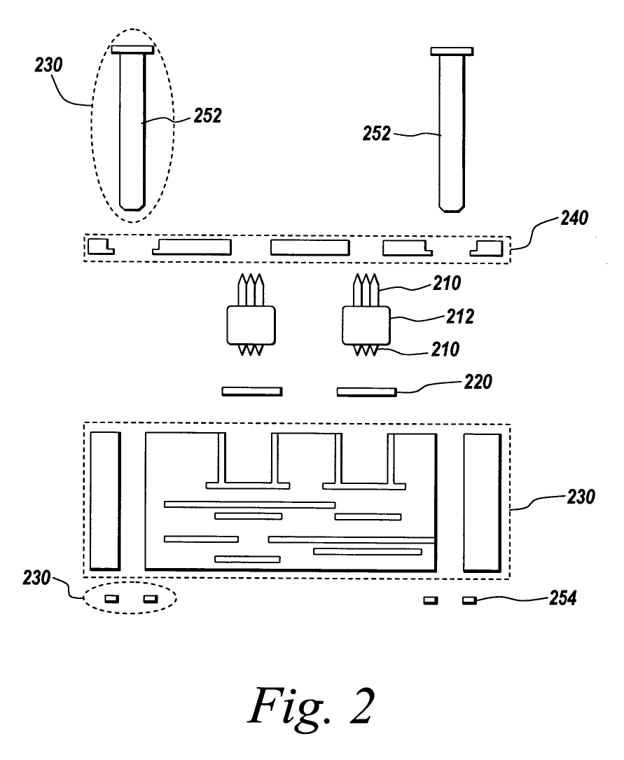

FIG. 2 shows the construction of a probe device having micro-pins inserted into an interface board according to an embodiment of the present invention.

The probe device having micro-pins inserted into an interface board according to an embodiment of the present invention, referring to FIG. 2, includes micro-pins 210, micro-pin contact portions 220, an interface board 230, a mask board 240, and a mask board retainer 250.

The micro-pins 210 are adapted to make direct contact with a semiconductor integrated circuit 150, which is to be inspected, and transmit an electric current thereto. The micro-pins 210 are made of a conductive material, for example, beryllium copper (BeCu), which is a copper-based alloy, iron alloy (SK4), tungsten, or titanium for better electrical conductance. In addition, the micro-pins 210 are made of a heat-treatable material for better strength.

The micro-pins 210 are divided into first and second micro-pins, between which coil springs are positioned, respectively. The first micro-pins make contact with electrode pads 152 of the semiconductor integrated circuit 150, and the second micro-pins make contact with the micro-pin contact portions 220, which are inserted into grooves of the interface board 230. Upon making contact with the electrode pads 152, the first micro-pins are inserted towards the second micro-pins by the coil spring. The contact between the first and second micro-pins causes the electric current of the probe device to be transmitted to the semiconductor integrated circuit 150.

The micro-pins 210 are enclosed by retaining blocks 212, in which the coil springs are positioned. The retaining blocks 212 have the shape of a cylinder with openings at the top and bottom. The upper end of the retaining blocks 212 is bent inwards to prevent the micro-pins 212 from protruding to the exterior of the retaining blocks 212. The retaining blocks 212 are made of an insulating material, preferably PEI (polyether imide) having a specific dielectric constant of about 3.15, engineering plastic (TORON) with good strength and workability, or ceramic (alumina).

Although the micro-pins 210 have been described to include first and second micro-pins together with coil springs, they may have different construction as desired. For example, the micro-pins are of the same type and have a protrusion, and coil springs engage with the protrusions to regulate the contraction and extension of the micro-pins. Alternatively, one of two interconnected micro-pins is partially inserted into the other. In addition, although the coil springs have been described to provide only elastic restoring force, they may also be made of a conductive material so that an electric current can be transmitted between the first and second micro-pins via the coil springs.

The micro-pin contact portions 220 transmit a signal or electric current between the micro-pins 210 and the interface board 230 and are made of metal having good resistance to corrosion and wear, as well as good electrical conductivity, such as gold or platinum. For good contact properties, a dry plating method is utilized. As used herein, the dry plating method refers to a method of coating metal using a device for sputter or chemical vapor deposition, for example.

The interface board 230 is a multi-layered printed circuit board or ceramic laminated board and is adapted to match impedance for transmitting an electric current, which is necessary to test the semiconductor integrated circuit 150. According to the present invention, the interface board 230 has grooves and holes formed thereon, into which the micro-pins 210 and the mask board retainer 250 are inserted, respectively.

The mask board 240 is mounted on the interface board 230 to retain the micro-pins 210, which are inserted into the interface board 230, and prevent them from escaping. To this end, the mask board 240 has holes formed thereon, through which the micro-pins 210 can protrude. The mask board 240 has protrusions formed on the top thereof to retain the semiconductor integrated circuit 150, which is to be inspected, so that the electrode pads 152 correspond to the micro-pins 210 one by one. Preferably, the mask board 240 is made of an insulating material to minimize interference with the micro-pins 210.

The mask board retainer 250 is adapted to retain the mask board 240 on the interface board 230. In general, the mask board retainer 250 includes retaining bolts and nuts 252 and 254. Alternatively, guide pins may be used instead of the retaining bolts 252. In addition, the nuts 254 may be replaced by screwed grooves formed inside the interface board 230.

The above components are assembled to constitute a probe device, which has micro-pins inserted into an interface board.

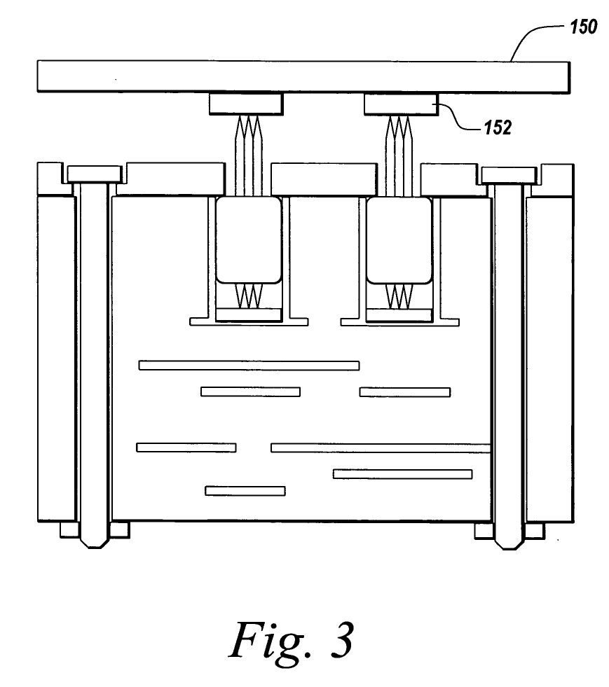

FIG. 3 is a sectional view showing a probe device having micro-pins inserted into an interface board according to an embodiment of the present invention.

The interface board 230 of the probe device has the same number of grooves as the micro-pins 210 inserted therein. A micro-pin contact portion 220 and a micro-pin 210 are inserted into each groove, which has a depth large enough to completely receive the retaining block 212 of the micro-pin 210.

After the micro-pin contact portions 220 and the micro-pins 210 are inserted into the grooves of the interface board 230, a mask board 240 is mounted thereon in such a manner that the micro-pins 210 protrude through holes of the mask board 240. The holes of the mask board 240 are dimensioned in such a manner that the micro-pins 210 protrude through the holes, but not the retaining blocks 212, which enclose the micro-pins 210.

The mask board 240 is retained on the interface board 230 using retaining bolts 252 and nuts 254. At least two retaining bolts 252 and nuts 254 are used for reliable retaining.

After the probe device is constructed in this manner, the micro-pins 210 are brought into contact with electrode pads 152 of a semiconductor integrated circuit 150 to check whether it is defective or not.

As mentioned above, the probe device according to the present invention includes an interface board having grooves formed thereon, micro-pins inserted into the grooves, and a mask (mask board) for covering the board. Therefore, the probe device can be constructed in a simple assembly process without soldering. This substantially reduces manufacturing time and cost. In addition, the probe device can be easily repaired, when the micro-pins or micro-pin contact portions malfunction and the test fails, by separating the retaining screws, removing the mask board, replacing defective micro-pins or micro-pin contact portions, mounting the mask board again, and retaining the mask board using the retaining screws.

In contrast to conventional probe devices, which use a housing to retain the micro-pins, furthermore, the micro-pins are inserted into the grooves of the interface board according to the present invention. This guarantees accurate contact and substantially reduces the manufacturing cost and the defective ratio. In addition, accurate inspection is possible even in the case of a circuit having a fine pitch of 100 μm or less.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A probe device for testing a semiconductor integrated circuit comprising:
a micro-pin adapted to make direct contact with the semiconductor integrated circuit and transmit an electric current to the semiconductor integrated circuit;
a retaining block enclosing the micro-pin;
an interface board having a groove, the micro-pin being inserted into the groove, to transmit an electric current to the semiconductor integrated circuit via the micro-pin;
a micro-pin contact portion for improving contact between the micro-pin and the interface board;
a mask board mounted on the interface board to retain the micro-pin so that the micro-pin does not detach from the interface board; and
a mask board retainer for retaining the mask board on the interface board.

2. The probe device as claimed in claim 1, wherein the micro-pin comprises a first micro-pin, a second micro-pin, and a coil spring, and the first and second micro-pins are operated up and down through contraction and extension.

3. The probe device as claimed in claim 1, wherein the mask board has a hole dimensioned so that the micro-pin can protrude but the retaining block cannot protrude.

4. The probe device as claimed in claim 1, wherein the micro-pin contact portion is formed as a coating by a dry plating method to improve contact between the micro-pin and the interface board.

5. The probe device as claimed in claim 1, wherein the mask board retainer comprises a retaining bolt and a retaining nut, and the retaining bolt is coupled to the retaining nut through the mask board and the interface board.

6. The probe device as claimed in claim 1, wherein the interface board has a screw-shaped groove, when the mask board retainer comprises a retaining bolt, to retain the retaining bolt.
